(19) United States
(12) Patent Application Publication
(10) Pub. No.: US 2018/0033789 A1
(43) Pub. Date: Feb. 1, 2018

(54) METHOD, APPARATUS, AND SYSTEM FOR REDUCING DOPANT CONCENTRATIONS IN CHANNEL REGIONS OF FINFET DEVICES

(71) Applicants: GLOBALFOUNDRIES INC., Grand Cayman (KY); International Business Machines Corporation, Armonk, NY (US)

(72) Inventors: Steven Bentley, Watervliet, NY (US); Kwan-Yong Lim, Niskayuna, NY (US); Tenko Yamashita, Schenectady, NY (US); Gauri Karve, Cohoes, NY (US); Sanjay Mehta, Niskayuna, NY (US)

(73) Assignees: GLOBALFOUNDRIES INC., Grand Cayman (KY); International Business Machines Corporation, Armonk, NY (US)

(21) Appl. No.: 15/224,139

(22) Filed: Jul. 29, 2016

(51) Int. Cl. H01L 27/092; H01L 21/306; H01L 21/762; H01L 21/266; H01L 29/10; H01L 29/06; H01L 21/265; H01L 21/8238; H01L 29/167

(52) U.S. Cl. CPC H01L 27/0924; H01L 21/823821; H01L 21/30604; H01L 21/823878; H01L 21/76224; H01L 29/167; H01L 29/1033; H01L 29/0649; H01L 21/26513; H01L 21/266

(57) ABSTRACT

We disclose semiconductor devices, comprising a semiconductor substrate comprising a substrate material; and a plurality of fins disposed on the substrate, each fin comprising a lower region comprising the substrate material, a dopant region disposed above the lower region and comprising at least one dopant, and a channel region disposed above the dopant region and comprising a semiconductor material, wherein the channel region comprises less than 1×10¹⁸ dopant molecules/cm³, as well as methods, apparatus, and systems for fabricating such semiconductor devices.

### BACKGROUND OF THE INVENTION

### Field of the Invention

Generally, the present disclosure relates to the manufacture and use of sophisticated semiconductor devices, and, more specifically, to various methods, structures, and systems for reducing dopant concentrations in channel regions of FinFET devices.

### Description of the Related Art

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another. In this manner, integrated circuit chips may be fabricated.

A typical integrated circuit (IC) chip includes a stack of several levels or sequentially formed layers of shapes. Each layer is stacked or overlaid on a prior layer and patterned to form the shapes that define devices (e.g., fin field effect transistors (FinFETs)) and connect the devices into circuits. In a typical state of the art complementary insulated gate FinFET process, a fin (rectangular in cross-section) is formed on a surface of the wafer, and a gate is formed over the fin. The fin may comprise a channel region. The fins may also comprise a punch-through stopper region below a channel region to reduce leakage and/or parasitic channel formation. The punch-through stopper region may be formed by introducing a suitable dopant through the channel region, followed by annealing of the dopant to form the punch-through stopper region. Thereafter, subsequent processing steps, which may involve techniques performed at relatively high temperature, may be performed to produce a final semiconductor device.

A number of undesirable effects may occur when manufacturing a FinFET device comprising a punch-through stopper. For example, during introduction, some dopant molecules may fail to traverse the channel region. As a result, the channel region may have degraded mobility. For another example, during high temperature techniques performed subsequently to punch-through stopper formation, dopant molecules may diffuse into the channel region. If either event occurs, the channel region of the final semiconductor device may have a relatively high dopant concentration, e.g., greater than about 1×10¹⁸ dopant molecules/cm³.

A number of known attempts to solve this problem have been tried, but found wanting. First, introducing a punch-through stopper at a later stage of processing still leaves dopant in the channel region of the fin, and can introduce lattice defects or cause amorphization in the active channel portion of the fin. Either event impairs mobility of the channel region. Second, doped films comprising, e.g., boron silicate glass (BSG) or phosphorous silicate glass (PSG) can be deposited on tops and sidewalls of fins, including the channel regions, followed by deposition of a liner over the doped films and deposition of a shallow trench isolation (STI) material over the liner. Generally, the combined thickness of the doped film and liner layer on each fin sidewall is in the range of 5-8 nm. To be effective, the doped film must be completely stripped from the channel regions of the fin, and anneal of the STI material must be performed at low temperatures to prevent drive-in of dopant into the channel regions. Further, because the thickness of doped films and liner layers between adjacent fins is in the range of 10-16 nm, this technique is difficult to implement in the 7-14 nm scales currently being brought online.

Therefore, it would be desirable to have FinFETs with reduced dopant concentration in channel regions. It would further be desirable for such FinFETs to be free of residual layers between fin sidewalls and STI materials.

The present disclosure may address and/or at least reduce one or more of the problems identified above regarding the prior art and/or provide one or more of the desirable features listed above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to semiconductor devices, comprising a semiconductor substrate comprising a substrate material; and a plurality of fins disposed on the substrate, each fin comprising a lower region comprising the substrate material, a dopant region disposed above the lower region and comprising at least one dopant, and a channel region disposed above the dopant region and comprising a semiconductor material, wherein the channel region comprises less than 1×10¹⁸ dopant molecules/cm³, as well as methods, apparatus, and systems for fabricating such semiconductor devices.

Semiconductor devices in accordance with embodiments of the present disclosure may provide reduced dopant content in channel regions, thereby having improved properties not available to prior art semiconductor devices.

### BRIEF DESCRIPTION OF THE DRAWINGS

The disclosure may be understood by reference to the following description taken in conjunction with the accompanying drawings, in which like reference numerals identify like elements, and in which:

FIG. 1A illustrates a semiconductor device in accordance with embodiments herein, after a first processing event;

FIG. 1B illustrates the semiconductor device in accordance with embodiments herein, after a second processing event;

FIG. 1C illustrates the semiconductor device in accordance with embodiments herein, after a third processing event;

FIG. 1D illustrates the semiconductor device in accordance with embodiments herein, after a fourth processing event;

FIG. 1E illustrates the semiconductor device in accordance with embodiments herein after a fifth processing event;

FIG. 1F illustrates the semiconductor device in accordance with embodiments herein after a sixth processing event;

FIG. 1G illustrates the semiconductor device in accordance with embodiments herein after a seventh processing event;

FIG. 1H illustrates the semiconductor device in accordance with embodiments herein after an eighth processing event;

FIG. 1I illustrates the semiconductor device, in accordance with embodiments herein after a ninth processing event;

FIG. 1J illustrates the semiconductor device in accordance with embodiments herein after a tenth processing event;

FIG. 1K illustrates the semiconductor device in accordance with embodiments herein after an eleventh processing event;

FIG. 1L illustrates the semiconductor device in accordance with embodiments herein after a twelfth processing event;

FIG. 1M illustrates the semiconductor device in accordance with embodiments herein after a thirteenth processing event;

FIG. 1N illustrates the semiconductor device in accordance with embodiments herein after a fourteenth processing event;

FIG. 1O illustrates the semiconductor device in accordance with embodiments herein after a fifteenth processing event;

FIG. 1P illustrates the semiconductor device in accordance with embodiments herein after a sixteenth processing event;

FIG. 1Q illustrates the semiconductor device in accordance with embodiments herein after a seventeenth processing event;

FIG. 1R illustrates the semiconductor device in accordance with embodiments herein after an eighteenth processing event;

FIG. 1S illustrates the semiconductor device in accordance with embodiments herein after a nineteenth processing event; and

FIG. 1T illustrates the semiconductor device in accordance with embodiments herein after an alternative nineteenth processing event;

FIG. 1U illustrates the semiconductor device in accordance with embodiments herein after a twentieth processing event;

FIG. 1V illustrates the semiconductor device in accordance with embodiments herein after a twenty-first processing event;

FIG. 1W illustrates the semiconductor device in accordance with embodiments herein after a twenty-second processing event;

FIG. 2 illustrates a semiconductor device manufacturing system for manufacturing a device in accordance with embodiments herein; and

FIG. 3 illustrates a flowchart of a method in accordance with embodiments herein.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for FinFET semiconductor devices which may have reduced dopant concentrations (e.g., less than 1×10¹⁸ dopant molecules/cm³) in channel regions of fins. Alternatively or in addition, the FinFET devices may be free of residual layers between fin sidewalls and STI materials.

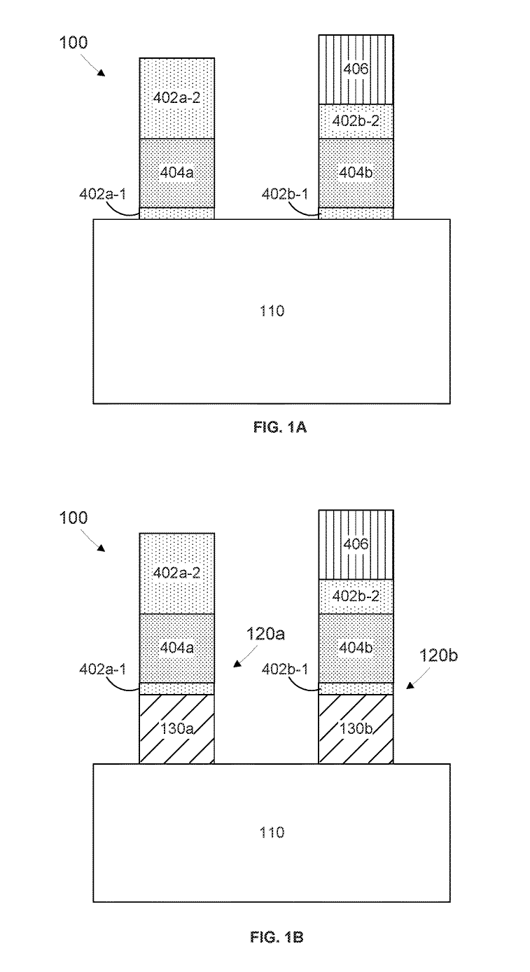

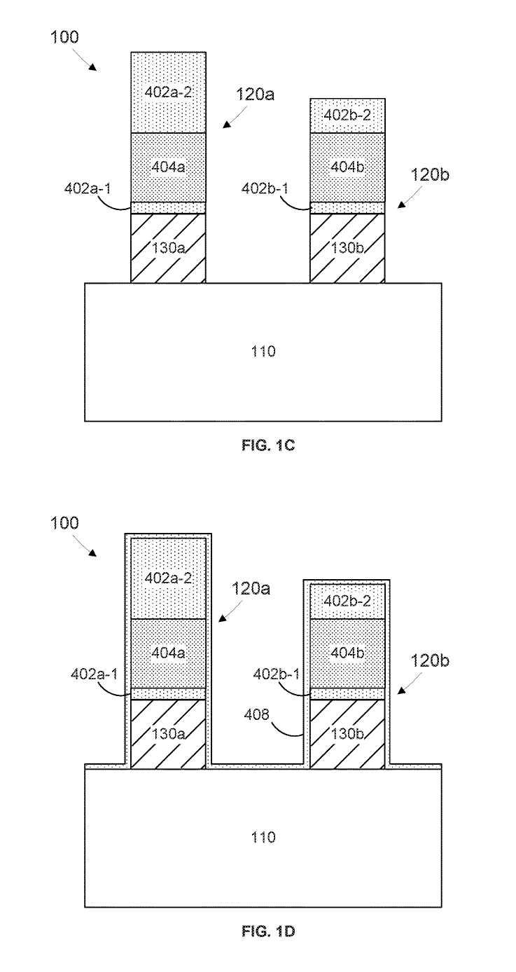

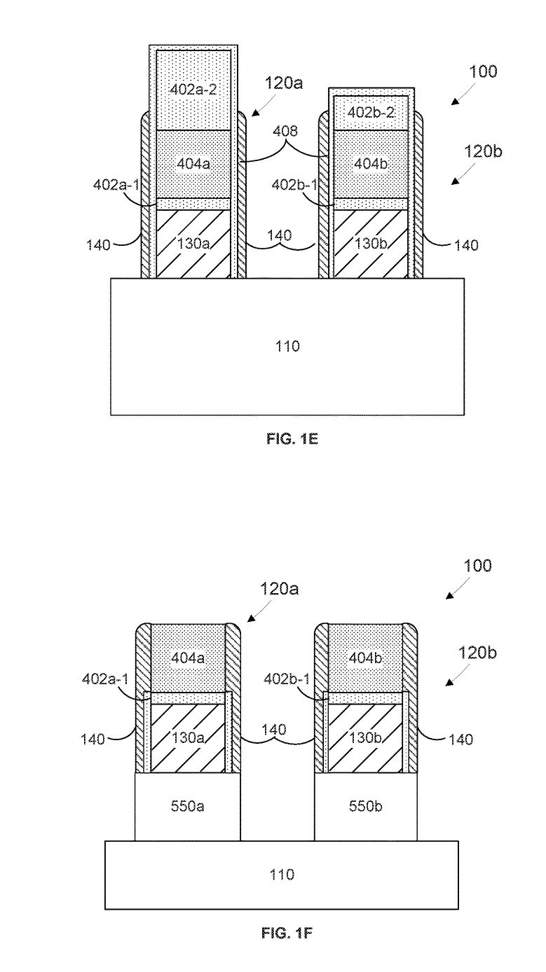

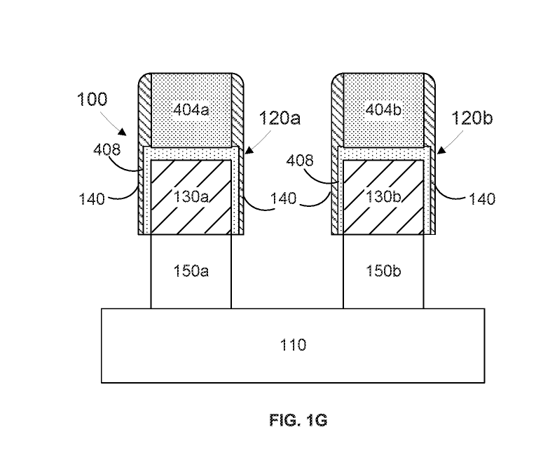

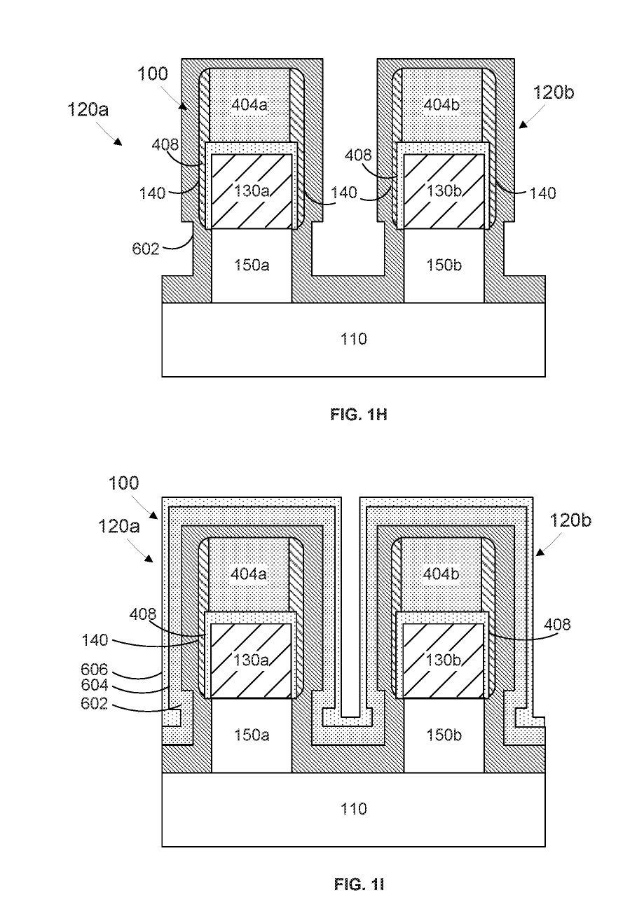

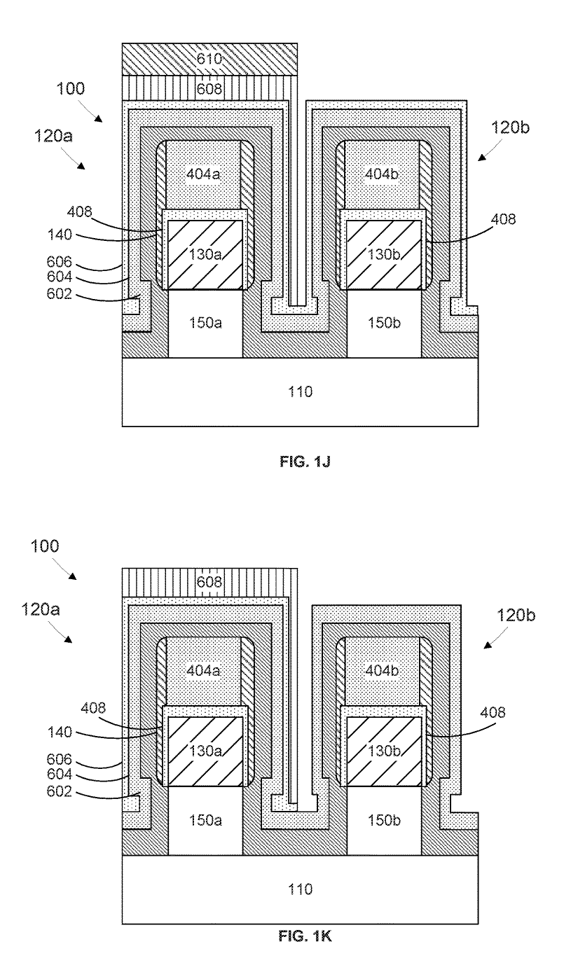

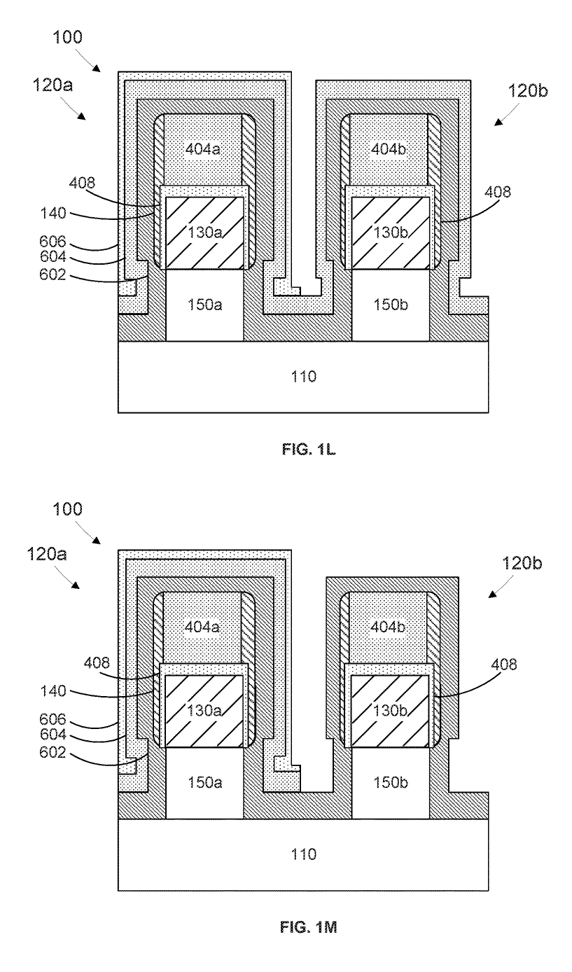

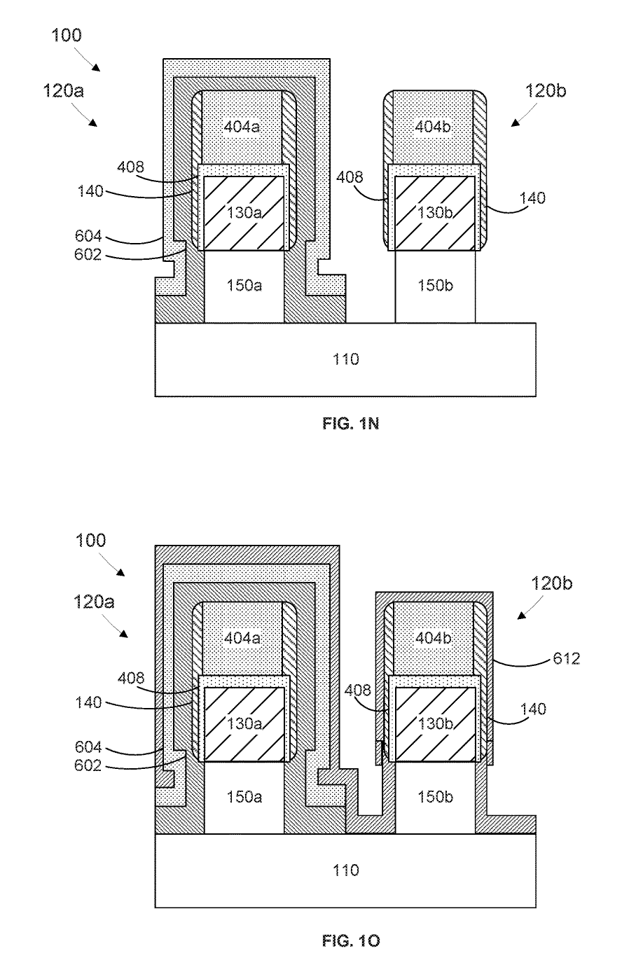

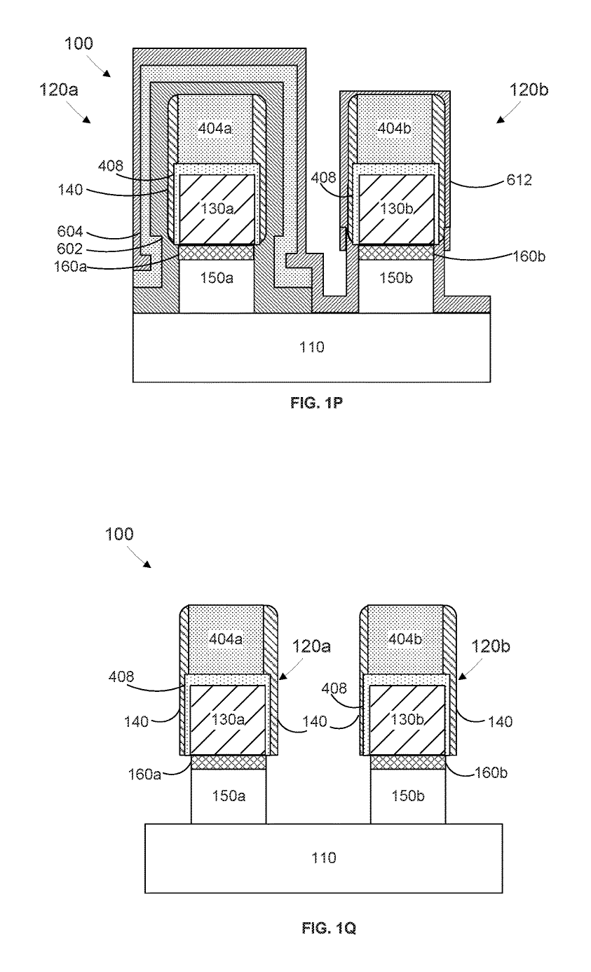

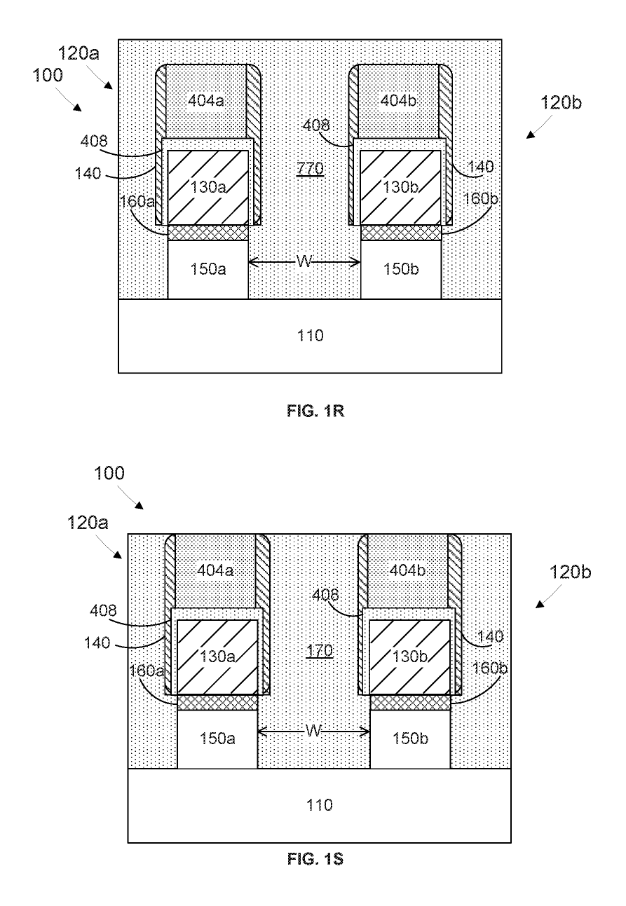

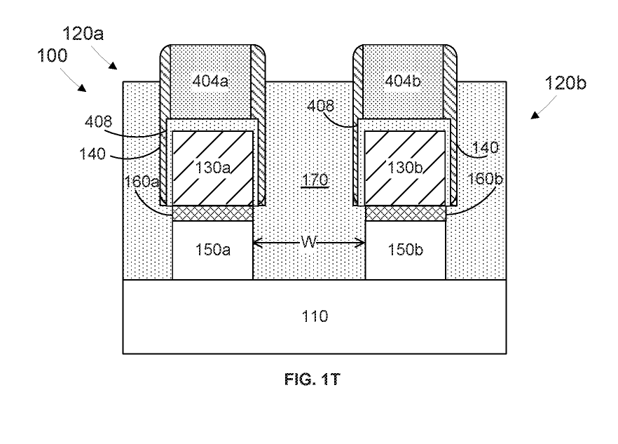

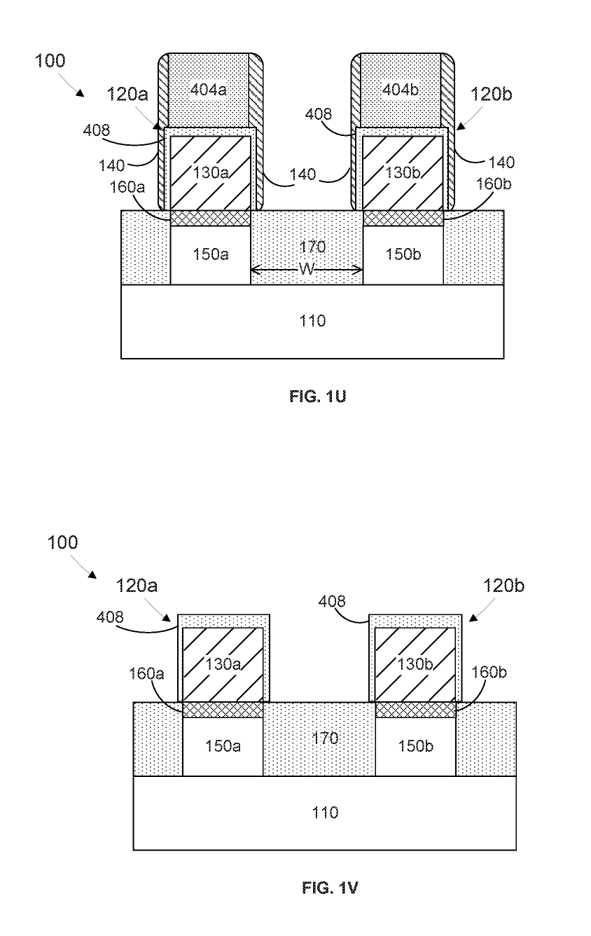

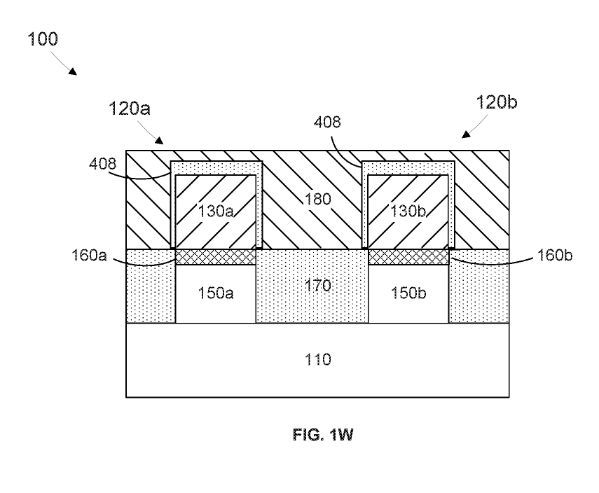

In one embodiment, the present disclosure relates to a semiconductor device 100, such as is stylistically depicted at various stages of fabrication in FIGS. 1A-1W.

Turning to FIG. 1A, one or more oxide layers 402, nitride layers 404, and/or organic planarization layers 406 may be formed on a substrate 110. The substrate material may be any semiconductor material, such as bulk silicon, silicon-on-insulator, silicon-germanium (SiGe), a III-V material, or two or more thereof. For example, the semiconductor substrate 110 may comprise silicon under a first subset of fins 120 and SiGe under a second subset of fins 120 (not shown). Similarly, the semiconductor material of the channel regions 130 may be any suitable material. In one embodiment, the semiconductor material is selected from silicon or silicon-germanium (SiGe). In embodiments, the semiconductor substrate 110 and the channel regions 130 may comprise the same materials.

An active fin etch may then be performed, using the oxide layers 402, nitride layers 404, and/or organic planarization layers 406 for patterning to form channel regions 130 of fins 120 as shown in FIG. 1B. In other embodiments (not shown), one or more of oxide layers 402, nitride layers 404, and/or organic planarization layers 406 may be omitted.

After forming the channel regions 130, organic planarization layers 406 may be stripped (as shown in FIG. 1C) and an oxide layer 408 may be formed on exposed surfaces, including a first side and a second side of the channel regions 130 (as shown in FIG. 1D). Such an oxide layer may be formed by an oxidation process such as in situ steam generation (ISSG) or a deposition process such as atomic layer deposition (ALD).

At the stage shown in FIG. 1D, the semiconductor device 100 comprises a plurality of fins 120a, 120b on a semiconductor substrate 110 comprising a substrate material, each fin comprising a channel region 130a, 130b comprising a semiconductor material.

For the avoidance of doubt, although only two fins 120 are depicted in FIGS. 1A-1W, the person of ordinary skill in the art will understand that more than two fins 120 may be included in a semiconductor device 100 according to the present invention.

Turning to FIG. 1E, the semiconductor device 100 is depicted after a fifth processing event, in which a block layer 140 (which may also be referred to herein as a spacer layer) is formed on at least a first side and a second side of at least the channel region 130a, 130b of each fin 120a, 120b. The block layer 140 may comprise any material suitable for blocking the diffusion of dopant described below. In one embodiment, the block layer 140 may comprise silicon nitride or a material having a low dielectric constant, such as silicon boron carbon nitride (SiBCN). As shown in FIG. 1E, the block layer 140 may be formed to cover some or all of the sides of oxide layers 402, nitride layers 404, and/or oxide layer 408 disposed on or above channel regions 130.

As shown in FIG. 1F, a sixth processing event may comprise etching the fins 120 to have an initial lower region 550 width equal to the combined width of a channel region 130 and two block layers 140. Subsequently, as shown in FIG. 1G, an isotropic etchback may be performed to narrow the lower regions 150 to the same width as, or narrower than, channel regions 140. Lower regions 150a, 150b comprise the substrate material. As depicted, the block layer 140 does not cover either side of lower regions 150. However, an isotropic etchback may be omitted, and the width of lower regions 550 may remain equal to the combined width of a channel region 130 and two block layers 140 as the semiconductor device 100 is subjected to subsequent processing events.

FIGS. 1H-1P show an eighth through a sixteenth processing event. As shown in FIG. 1H, a first dopant-containing film layer 602 (e.g., a boron silicate glass (BSG) layer) may be deposited over the semiconductor device 100. Thereafter, a silicon nitride layer 604 may be deposited over the first dopant-containing film layer 602 and an oxide layer 606 may be deposited over the silicon nitride layer 604, to yield the semiconductor device shown in FIG. 1I. FIG. 1J shows masking at least a first subset of fins 120a, such as with an organic planarization layer (OPL) 608 and, optionally, a masking layer 610 above the OPL 608, thereby leaving a second subset of fins 120b exposed. The oxide layer 606 may be removed from the second subset of fins 120b, such as by wet etching (for example, in an HF-containing solution), or a dry reactive clean such as SiCoNi or COR, or using a reactive ion etch, to yield the semiconductor device shown in FIG. 1K, in which also optional masking layer 610 has also been removed. FIG. 1L shows the semiconductor device 100 following removal of the OPL 608, thereby leaving the first subset of fins 120a with an outermost oxide layer 606 and the second subset of fins 120b with an outermost nitride layer 604.

Subsequently, as shown in FIG. 1M, the nitride layer 604 may be stripped from the second subset of fins 120b. The oxide layer 606 may then be stripped from the first subset of fins 120a and the first dopant-containing film layer 602 from the second subset of fins 120b, such as by COR/SiCoNi/BHF, thereby leaving the first subset of fins 120a with an outermost nitride layer 604 and the second subset of fins 120b with exposed lower regions 150, as shown in FIG. 1N.

Thereafter, a second dopant-containing film layer 612 (e.g., a phosphorous silicate glass (PSG)) may be deposited over the semiconductor device 100, as shown in FIG. 1O. A drive-in anneal of first dopant (e.g., boron) from the first dopant-containing film layer 602 to yield dopant regions 160a disposed below the channel regions 130a of the first subset of fins 120a and second dopant (e.g., phosphorous) from the second dopant-containing film layer to yield dopant regions 160b disposed below the channel regions 130b of the second subset of fins 120b may then be performed (FIG. 1P). Each dopant region 160 may be a continuous band across the full width of each fin 120. Although dopant may be present in other regions of lower portions 150, the block layers 140 may reduce the amount of dopant entering channel regions 130a, 130b. In one embodiment, in a first subset of fins, the dopant 160a is boron, and in a second subset of fins, the dopant 160b is phosphorous.

Various layers (e.g., first dopant-containing film layer 602, nitride layer 604, and second dopant-containing film layer 612) remaining on the first and/or second subsets 120a, 120b of fins 120 after introduction of the dopant may be removed after formation of dopant regions 160a, 160b, as a routine matter for the person of ordinary skill in the art having the benefit of the present disclosure, thereby arriving (if desired) at the semiconductor device 100 depicted in FIG. 1Q. However, in other embodiments (not shown), the first dopant-containing film layer 602, second dopant-containing film layer 612, etc. may be retained throughout the STI deposition, anneal, and recess events described below, and removed prior to removal of the nitride layer 604.

In one embodiment, as shown in FIGS. 1R-1T, the eighteenth and nineteenth processing events may comprise using as-deposited unannealed STI material 770 to above the top of fins 120 (FIG. 1R), which may then be annealed to yield the STI material 170, followed by chemical mechanical polishing (CMP) to lower the top of the STI material 170 to the top of the fins 120 (FIG. 1S). Thereafter, the STI material 170 may be recessed by conventional techniques to expose portions of the fins 120 above the dopant layers 160 and above the bottoms of spacer layers 140, i.e., to yield the semiconductor device 100 shown in FIG. 1T, or to expose portions of the fins 120 above the dopant layers 160 and to the bottoms of spacer layers 140, i.e., to yield the semiconductor device 100 shown in FIG. 1U.

In one embodiment, the width (W) of the STI material between each pair of adjacent fins is at least 3 nm. Regardless of the width of the STI material, the semiconductor device 100 may be free of residual layers between sidewalls of fins 120 and STI material 170; i.e., lower regions 150 and STI material 170 may be in direct physical contact.

Turning to FIG. 1V, the semiconductor device 100 after a twentieth processing event is depicted. In the twentieth processing event, the block layer 140 may be removed from each fin 120. For example, the block layer 140 (and, if present and as shown, nitride layers above the channel regions 130 of the fins 120) may be removed by a wet etch in hot phosphoric acid or by a dry reactive clean technique, particularly if an oxide layer is disposed above and on the sides of channel regions 130 of the fins 120. Further, any portions of one or more layers disposed above the channel regions 130, such as a nitride layer 404, which may be exposed after recessing the STI material 170 may then be removed with a wet/dry etch sequence and/or hard mask strip.

FIG. 1W depicts the semiconductor device 100 after a twenty-second processing event, in which a gate structure 180 is formed over the channel region 130a, 130b. The gate structure 180 may be in electrical contact with channel regions 130.

To summarize, in one embodiment in accordance with the present disclosure, a semiconductor device 100 may comprise a semiconductor substrate 110 comprising a substrate material; a plurality of fins 120 disposed on the substrate 110, each fin comprising a lower region 150a, 150b comprising the substrate material, a dopant region 160a, 160b disposed above the lower region 150a, 150b and comprising at least one dopant, and a channel region 130a, 130b disposed above the dopant region 160a, 160b and comprising a semiconductor material (such as silicon or SiGe), wherein the channel region 130a, 130b may comprise less than 1×10¹⁸ dopant molecules/cm³. In one embodiment, in a first subset of fins, the dopant is boron, and in a second subset of fins, the dopant is phosphorous.

The semiconductor device 100 may further comprise a block layer 140, such as a nitride layer, disposed on a first side and a second side of the channel regions 130 of fins 120. The semiconductor device 100 may also comprise a shallow trench isolation (STI) material 170 disposed between each pair of adjacent fins 120, wherein a top of the STI material 170 is at least as high as a top of dopant regions 160.

In one embodiment, the width of the STI material between each pair of adjacent fins is at least 3 nm. This condition may be achieved even if exposed first dopant-containing film layer and second dopant-containing film layer are removed after STI deposition, anneal, and recessing, i.e., if some first dopant-containing film layer and second dopant-containing film layer disposed on the lower regions 150 remain present when STI 170 is formed thereupon. Alternatively or in addition, lower regions 150 and STI material 170 may be in direct physical contact.

In an additional embodiment, the semiconductor device 100 may further comprise a gate structure 180 disposed over the channel regions 160.

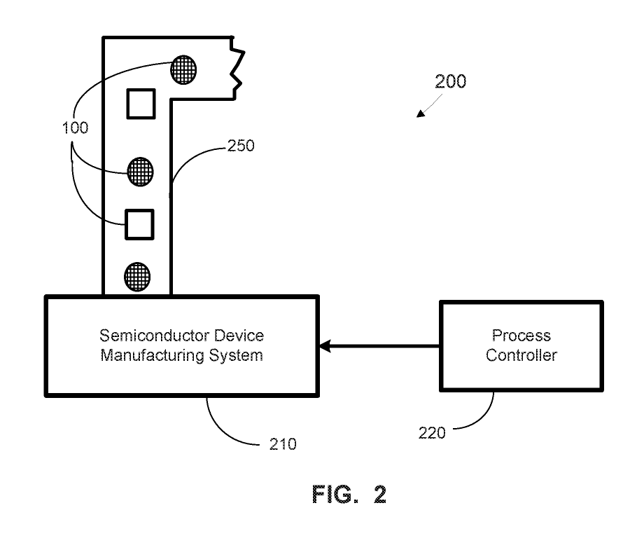

Turning now to FIG. 2, a stylized depiction of a system for fabricating a semiconductor device 100, in accordance with embodiments herein, is illustrated. The system 200 of FIG. 2 may comprise a semiconductor device manufacturing system 210 and a process controller 220. The semiconductor device manufacturing system 210 may manufacture semiconductor devices 100 based upon one or more instruction sets provided by the process controller 220. In one embodiment, the instruction set may comprise instructions to form a plurality of fins on a semiconductor substrate comprising a substrate material, each fin comprising a channel region comprising a semiconductor material; form a block layer on a first side and a second side of at least the channel region of each fin; etch the semiconductor substrate between each pair of adjacent fins, thereby forming a lower region of each fin, wherein the lower region comprises the substrate material; and introduce at least one dopant into a portion of the lower region adjacent to the channel region, thereby forming a dopant region disposed above the lower region and below the channel region.

Upon execution of the instruction set by the semiconductor device manufacturing system 210, the distance between adjacent fins may be at least 3 nm. Alternatively or in addition, lower regions 140 and STI material 170 may be in direct physical contact.

In one embodiment, the channel region of the semiconductor device may comprise less than 1×10¹⁸ dopant molecules/cm³.

In one embodiment, the instruction set may further comprise instructions to deposit a shallow trench isolation (STI) material between each pair of adjacent fins, wherein a top of the STI material is at least as high as a top of the dopant region; and remove the block layer from each fin. The instruction set may comprise instructions to form the STI material between each pair of adjacent fins with a width of at least 3 nm and/or to form lower regions and STI material in direct physical contact.

In a further embodiment, the instruction set may further comprise instructions to form a gate structure over the channel region.

The semiconductor device manufacturing system 210 may be used to manufacture a semiconductor device 100 having a low dopant concentration, such as less than 1×10¹⁸ dopant molecules/cm³, in the channel region.

The semiconductor device manufacturing system 210 may comprise various processing stations, such as etch process stations, photolithography process stations, CMP process stations, etc. One or more of the processing steps performed by the semiconductor device manufacturing system 210 may be controlled by the process controller 220. The process controller 220 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device manufacturing system 210 may produce semiconductor devices 100 (e.g., integrated circuits) on a medium, such as silicon wafers. The semiconductor device manufacturing system 210 may provide processed semiconductor devices 100 on a transport mechanism 250, such as a conveyor system. In some embodiments, the conveyor system may be sophisticated clean room transport systems that are capable of transporting semiconductor wafers. In one embodiment, the semiconductor device manufacturing system 210 may comprise a plurality of processing steps, e.g., the 1^{st} process step, the 2^{nd} process step, etc.

In some embodiments, the items labeled “100” may represent individual wafers, and in other embodiments, the items 100 may represent a group of semiconductor wafers, e.g., a “lot” of semiconductor wafers.

The system 200 may be capable of manufacturing various products involving various FinFET technologies, e.g., the system 200 may produce devices of CMOS technology, Flash technology, BiCMOS technology, power devices, memory devices (e.g., DRAM devices), NAND memory devices, and/or various other semiconductor technologies.

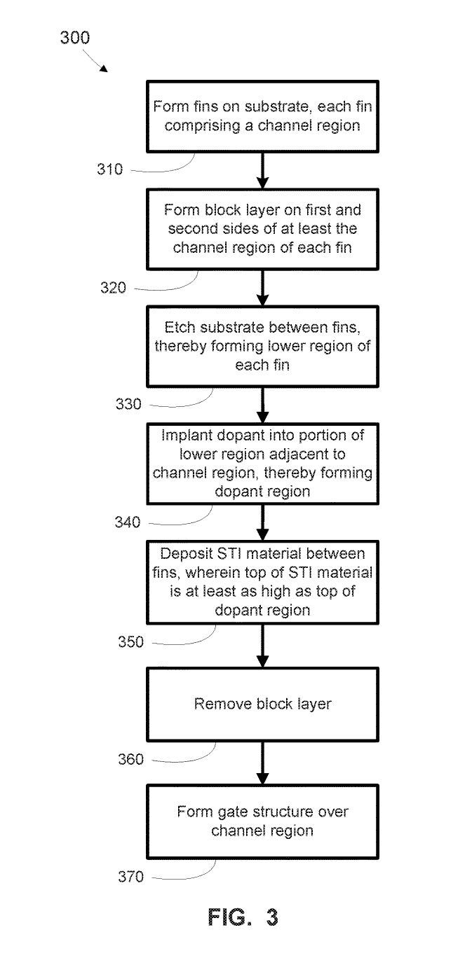

Turning to FIG. 3, a flowchart of a method 300 in accordance with embodiments herein is depicted. The method 300 may comprise forming (at 310) a plurality of fins on a semiconductor substrate comprising a substrate material, each fin comprising a channel region comprising a semiconductor material. In one embodiment, the semiconductor material may be selected from silicon or silicon-germanium (SiGe). In one embodiment, the space between each pair of adjacent fins is at least 3 nm.

The method 300 may further comprise forming (at 320) a block layer on a first side and a second side of at least the channel region of each fin. In one embodiment, the block layer may comprise nitride.

The method 300 may also comprise etching (at 330) the semiconductor substrate between each pair of adjacent fins, thereby forming a lower region of each fin, wherein the lower region comprises the substrate material. In addition, the method 300 may comprise introducing (at 340) at least one dopant into a portion of the lower region adjacent to the channel region, thereby forming a dopant region disposed above the lower region and below the channel region. In one embodiment, in a first subset of fins, the dopant is boron. Alternatively or in addition, in one embodiment, in a second subset of fins, the dopant is phosphorous.

Though not to be bound by theory, the presence of the block layer on the sides of the channel region of each fin may minimize dopant entry into the channel region. In one embodiment, after introducing (at 340), the channel region may comprise less than 1×10¹⁸ dopant molecules/cm³.

The method 300 may further comprise depositing (at 350) a shallow trench isolation (STI) material between each pair of adjacent fins, wherein a top of the STI material is at least as high as a top of the dopant region. In one embodiment, the width of the STI material between each pair of adjacent fins is at least 3 nm. Alternatively or in addition, lower regions and STI material may be in direct physical contact.

As should be apparent, “at least as high as a top of the dopant region” includes the top of the STI material being above a bottom of the block layer or being above a top of the block layer. Depending on the STI material deposited (at 350), the material may be annealed. In one embodiment, after depositing (at 350), the top of the STI layer may be lowered to any desired position by techniques known to the person of ordinary skill in the art having the benefit of the present disclosure.

Alternatively or in addition, the method 300 may comprise removing (at 360) the block layer from each fin. For example, removing (at 360) may involve a hot phos technique known to the person of ordinary skill in the art having the benefit of the present disclosure.

The method 300 may also comprise forming (at 370) a gate structure over the channel region.

The method 300 may produce a semiconductor device, wherein the semiconductor device has minimal dopant in the channel region, even after the performance of high temperature processing techniques on the semiconductor device.

The methods described above may be governed by instructions that are stored in a non-transitory computer readable storage medium and that are executed by, e.g., a processor in a computing device. Each of the operations described herein may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

Those skilled in the art having the benefit of the present disclosure would appreciate that other geometric shapes developed at the top portion of a fin in a similar manner described herein, may also provide the benefit of increased current drive without significant increase in current leakage. Therefore, a fin that has a lower portion disposed on the semiconductor substrate and having a first width, and an upper portion disposed on the lower portion and having a second width, wherein the second width is greater than the first width, may provide the benefit of increased drive current without significant increase in current leakage.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is, therefore, evident that the particular embodiments disclosed above may be altered or modified and all such variations are considered within the scope and spirit of the invention. Accordingly, the protection sought herein is as set forth in the claims below.

What is claimed is:

1. A method, comprising:
forming a plurality of fins on a semiconductor substrate comprising a substrate material, each fin comprising a channel region comprising a semiconductor material;
forming a block layer on a first side and a second side of at least the channel region of each fin;
etching the semiconductor substrate between each pair of adjacent fins, thereby forming a lower region of each fin, wherein the lower region comprises the substrate material; and
introducing at least one dopant into a portion of the lower region adjacent to the channel region, thereby forming a dopant region disposed above the lower region and below the channel region.

2. The method of claim 1, wherein the block layer comprises nitride.

3. The method of claim 1, wherein the semiconductor material is selected from silicon or silicon-germanium (SiGe).

4. The method of claim 1, further comprising:
depositing a shallow trench isolation (STI) material between each pair of adjacent fins, wherein a top of the STI material is at least as high as a top of the dopant region; and
removing the block layer from each fin.

5. The method of claim 4, wherein the width of the STI material between each pair of adjacent fins is at least 3 nm.

6. The method of claim 4, further comprising forming a gate structure over the channel region.

7. The method of claim 1, wherein in a first subset of fins, the dopant is boron, and in a second subset of fins, the dopant is phosphorous.

8. A semiconductor device, comprising:
a semiconductor substrate comprising a substrate material;
a plurality of fins disposed on the substrate, each fin comprising a lower region comprising the substrate material, a dopant region disposed above the lower region and comprising at least one dopant, and a channel region disposed above the dopant region and comprising a semiconductor material, wherein the channel region comprises less than 1×10¹⁸ dopant molecules/cm³.

9. The semiconductor device of claim 8, further comprising a block layer disposed on a first side and a second side of the channel region of each fin.

10. The semiconductor device of claim 9, wherein the block layer comprises nitride.

11. The semiconductor device of claim 8, wherein the semiconductor material is selected from silicon or silicon-germanium (SiGe).

12. The semiconductor device of claim 8, further comprising a shallow trench isolation (STI) material disposed between each pair of adjacent fins, wherein a top of the STI material is at least as high as a top of the dopant region.

13. The semiconductor device of claim 12, wherein the width of the STI material between each pair of adjacent fins is at least 3 nm.

14. The semiconductor device of claim 8, further comprising a gate structure disposed over the channel region.

15. The semiconductor device of claim 8, wherein in a first subset of fins, the dopant is boron, and in a second subset of fins, the dopant is phosphorous.

16. A system, comprising:
a process controller, configured to provide an instruction set for manufacture of a semiconductor device to a manufacturing system;
the manufacturing system, configured to manufacture the semiconductor device according to the instruction set, wherein the instruction set comprises instructions to:
form a plurality of fins on a semiconductor substrate comprising a substrate material, each fin comprising a channel region comprising a semiconductor material;
form a block layer on a first side and a second side of at least the channel region of each fin;
etch the semiconductor substrate between each pair of adjacent fins, thereby forming a lower region of each fin, wherein the lower region comprises the substrate material; and
introduce at least one dopant into a portion of the lower region adjacent to the channel region, thereby forming a dopant region disposed above the lower region and below the channel region.

17. The system of claim 16, wherein the channel region of the semiconductor device comprises less than 1×10¹⁸ dopant molecules/cm³.

18. The system of claim 16, wherein the instruction set further comprises instructions to:
deposit a shallow trench isolation (STI) material between each pair of adjacent fins, wherein a top of the STI material is at least as high as a top of the dopant region; and
remove the block layer from each fin.

19. The system of claim 18, wherein the instruction set further comprises instructions to:
form a gate structure over the channel region.

20. The system of claim 18, wherein the instruction set comprises instructions to form the STI material between each pair of adjacent fins with a width of at least 3 nm.
